(19) United States
(12) Patent Application Publication
(10) Pub. No.: US 2019/0334078 A1
(43) Pub. Date: Oct. 31, 2019

(54) PIEZOELECTRIC COMPOSITES COMPRISING A FLEXIBLE MATRIX

(71) Applicant: COMPAGNIE GENERALE DES ETABLISSEMENTS MICHELIN, Clermont-Ferrand (FR)

(72) Inventors: JOSÉ-CARLOS ARAUJO DA SILVA, Clermont-Ferrand (FR); MATHIEU ODDON, Clermont-Ferrand (FR)

(21) Appl. No.: 16/471,351

(22) PCT Filed: Dec. 20, 2017
(86) PCT No.: PCT/FR2017/053734

§ 371 Date: Jun. 19, 2019

(30) Foreign Application Priority Data
Dec. 20, 2016 (FR) 1662904

(51) Int. Cl. H01L 41/193; H01L 41/18; H01L 41/37; H01L 41/45

(52) U.S. Cl. CPC H01L 41/193; H01L 41/45; H01L 41/37; H01L 41/183

(57) ABSTRACT

A piezoelectric composite comprises a polymeric matrix and piezoelectric inorganic fillers in the form of particles which are not bound to the polymeric matrix but are dispersed in said polymeric matrix, characterized in that the polymeric matrix comprises a thermoplastic elastomer (TPE), in that the glass transition temperature, Tg, of each thermoplastic block of the thermoplastic elastomer (TPE) is lower than the lowest Curie temperature, Tc, of the piezoelectric inorganic fillers, moreover when the thermoplastic blocks have a melting point, Tm, said melting point of each thermoplastic block is also lower than the lowest Curie temperature of the piezoelectric inorganic fillers, and in that the filler content of the piezoelectric inorganic fillers is at least 5% by volume relative to the total volume of polymeric matrix. There are also a process for preparing such a piezoelectric composite, a device comprising such a composite, the use thereof and a tire comprising such a device.

### The present invention relates to a piezoelectric composite, the polymeric matrix of which comprises a thermoplastic elastomer.

Piezoelectricity develops in materials such as crystals, certain semicrystalline polymers and piezoelectric ceramics. This physical phenomenon corresponds to the appearance of an electrical polarization induced by an external mechanical deformation. It is an electromechanical coupling where the polarization is proportional to the mechanical stress applied up to a certain level. The piezoelectric effect is then said to be direct. This phenomenon is reversible: when the material is subjected to an external electric field, it is deformed. This is the inverse piezoelectric effect.

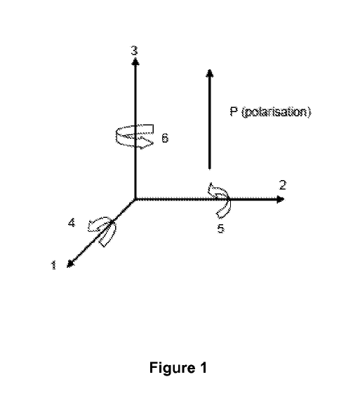

A variation in the macroscopic polarization when applying a stress on the sample characterizes the piezoelectric effect. In a system of orthogonal axes, the polarization and the stress are linked in matrix notation by a 2nd rank tensor referred to as piezoelectric tensor dij with i=1, 2, 3 and j=1, 2, 3, 4, 5, 6, respectively corresponding to the axis of polarization and of application of the stress as shown in FIG. 1.

A piezoactive or piezoelectric composite comprises at least one piezoelectric material, which gives the composite its piezoelectric activity, and one or more non-piezoelectric phases. This combination results in a material that has an increased performance compared to each phase alone. The non-piezoelectric phase is generally an organic polymer matrix, in particular a rigid thermoplastic or thermosetting polymer matrix (US 2015134061, WO 2016/157092), which may be of polyamide type (Capsal et al. Journal of non-crystalline solids 2010, 356, 629-634), polyepoxy type (Furukawa et al. Jpn. J. Appl. Phys. 1976, 15, 2119), polystyrene or polyurethane type (Hanner et al. Ferroelectrics 1989, 100, 255-260), PVC type (Liu et al. Materials Science and Engineering 2006, 127, 261-266) or else polyethylene type (Rujijanagul et al. Journal of Materials Science Letters 2001, 20, 1943-1945), or a polymeric matrix comprising cyanoethylated polyvinyl alcohol (EP 2654094). Thus, a piezoelectric composite makes it possible to maximize the electroactivity of the polymer matrix, but generally this combination also restricts its range of deformation.

In the field of tyres, devices that include piezoelectric composites are used as an apparatus for producing energy within a tyre. These devices make it possible to replace conventional limited-life batteries. In particular, the piezoelectric material may be embedded in an epoxy matrix (WO 03/095244 Michelin) or else in a thermoplastic, plastic or piezoelectric polymer matrix (US 2011/0074564).

One subject of the present invention is a piezoelectric composite comprising a polymeric matrix and piezoelectric inorganic fillers in the form of particles which are not bound to the polymeric matrix but are dispersed in said polymeric matrix, characterized in that the polymeric matrix comprises a thermoplastic elastomer (TPE), in that the glass transition temperature, Tg, of each thermoplastic block of the thermoplastic elastomer (TPE) is lower than the lowest Curie temperature, Tc, of the piezoelectric inorganic fillers, moreover when the thermoplastic blocks have a melting point, Tm, said melting point of each thermoplastic block is also lower than the lowest Curie temperature of the piezoelectric inorganic fillers, and in that the filler content of the piezoelectric inorganic fillers is at least 5% by volume relative to the total volume of polymeric matrix.

A piezoelectric composite in a flexible matrix according to the invention has particular electroactive and mechanical properties. Its formulation makes it possible to impart flexibility and elasticity to the composite material while retaining sufficient piezoelectric character for the application thereof in an electronic device.

The particular electromechanical properties of the electroactive composite according to the invention, such as its flexibility, elasticity, thermoplasticity and electric charge generation, have major advantages compared to thermosetting or thermoplastic matrix electroactive composites.
The thermoplasticity enables easier processability and shaping above the softening point, in particular with a controlled surface roughness geometry in order to apply electric charge-collecting electrodes.
The thermoplasticity also enables impact resistance.
The absence of a covalent bond between the matrix and the filler allows recycling of the components of the composite.
The elasticity allows different operating points, which is impossible with thermosetting or thermoplastic matrices that are brittle or that have plastic deformation.
The generation of electric charges with identical polarization is greater with a lower stress.

Furthermore, when each thermoplastic block of the thermoplastic elastomer has a glass transition temperature, Tg, lower than the Curie temperature, Tc, of the piezoelectric ceramic, the polarization may take place at a temperature that will make the phenomenon more effective.

Advantageously, the glass transition temperature and optionally the melting point of the thermoplastic blocks of the thermoplastic elastomer TPE is greater than or equal to 80° C.

In particular, the glass transition temperature of the elastomer blocks of the thermoplastic elastomer TPE is less than 25° C.

Advantageously, the thermoplastic elastomer TPE is a copolymer selected from the following group, consisting of linear or star-branched diblock or triblock copolymers: styrene/butadiene (SB), styrene/isoprene (SI), styrene/butadiene/isoprene (SBI), styrene/butadiene/styrene (SBS), styrene/isoprene/styrene (SIS), styrene/butadiene/isoprene/styrene (SBIS) and mixtures of these copolymers, advantageously the thermoplastic elastomer TPE is a SIS copolymer.

In particular, the content of piezoelectric inorganic fillers varies from 5% to 80% by volume relative to the total volume of polymeric matrix, advantageously from 5% to 60%, more advantageously still from 5% to 30%.

In particular, the size of the piezoelectric inorganic fillers varies from 50 nm to 500 μm.

Advantageously, the piezoelectric inorganic fillers are piezoelectric ceramics, in particular ferroelectric oxides, advantageously having a perovskite structure. In particular, the piezoelectric inorganic fillers are selected from the group comprising barium titanate, lead titanate, lead zirconate titanate (PZT), lead niobate, lithium niobate and potassium niobate fillers, advantageously the piezoelectric inorganic fillers are barium titanate fillers.

In particular, the thermoplastic elastomers TPE represent at least 90% by weight relative to the total weight of the polymeric matrix, advantageously at least 95% by weight, more advantageously still 100% by weight.

Another subject of the invention is a process for preparing a piezoelectric composite according to the invention comprising a step of polarizing the composite.

Advantageously, the polarization temperature is between the glass transition temperature, Tg, of each thermoplastic block of the TPE matrix and at least 5° C. lower than the Curie temperature, Tc, of the piezoelectric inorganic fillers.

In particular, the polarization temperature is between the glass transition temperature, Tg, of each thermoplastic block of the TPE matrix and at least 7° C. lower than the Curie temperature, Tc, of the piezoelectric inorganic fillers, advantageously at least 10° C. lower, than the lowest Curie temperature, Tc, of the piezoelectric inorganic fillers.

Another subject of the invention is a device comprising the piezoelectric composite according to the invention and electrodes.

Another subject of the invention is a tyre comprising the device mentioned above comprising the piezoelectric composite according to the invention and electrodes. In particular, said device is fastened to the inner airtight layer of said tyre.

Another subject of the invention is the use of said device mentioned above in combination with a sensor.

Measurements and Tests Used

Manufacture of the Test Specimens

The test specimens are of rectangular shape and have a thickness of a few millimetres. The composite material is shaped by hot pressing and then cut to the desired dimensions.

To facilitate the polarization and to enable the measurement, the test specimens are metallized on the lower and upper faces. The metallization may be carried out manually with a silver lacquer or by cathode sputtering or any other method known to those skilled in the art.

Polarization of the Samples

The output signal of a low-intensity generator is applied to the terminals of the test specimen (i.e. connected to the 2 metallized faces). The test specimens are thus polarized under a direct electric field of 4 kV, at the temperature of 100° C. and for 60 minutes. Once polarized, the sample is short-circuited to discharge as many residual charges as possible.

Equipment and Measurement

The measurement of the electromechanical response of these materials is performed on a dynamic measurement bed. The sample is pre-stretched by 1% then it is stressed in extension by 1 to 2% in strain at the frequency of 1 Hz and at ambient temperature.

The signal generated by the piezocomposite is recovered at the terminals of the sample by a specific jaws attachment, then amplified and measured on an oscilloscope.

From the peak-to-peak voltage read on the oscilloscope, the charge Q (pC) released upon each mechanical stress is deduced. Thus the piezoelectric coefficient d31 (pC/N) can be calculated. The coefficient d31, known to those skilled in the art, represents the coefficient measured by applying a stress in the direction orthogonal to the direction of polarization of the sample. In the case of a parallelepipedal sample, the direction of polarization corresponds to the smallest thickness (direction 3) and the stress is applied along the greatest length (direction 1).

The following notation may be adopted:

d31=ΔP3/Δσ1,

with ΔP3 being the macroscopic polarization variation in the direction 3 and Δσ1 the stress applied in the direction 1.

This coefficient is calculated by the following formula:

d31=[Q(pC)×thickness(m)]/[Force(N)×Length(m)]

in the case where the electrode covers the entire surface of the test specimen.

### DETAILED DESCRIPTION

In the present description, any interval of values denoted by the expression “from a to b” represents the range of values extending from a up to b (i.e. including the end points a and b). Any interval “between a and b” represents the range of values extending from more than a to less than b (i.e. end points a and b excluded).

The expression “particles which are not bound to the polymeric matrix” is understood to mean particles with no covalent bonds between the piezoelectric inorganic filler and the polymeric matrix.

The term “phr” is understood to mean “parts by weight per hundred parts of elastomer”, the thermoplastic elastomer TPE being included here in the elastomers.

1.1 Thermoplastic Elastomer (TPE)

Thermoplastic elastomers (abbreviated to “TPEs”) have a structure intermediate between thermoplastic polymers and elastomers. They are block copolymers consisting of rigid thermoplastic blocks connected by flexible elastomer blocks.

The thermoplastic elastomer used for the implementation of the invention is a block copolymer, the chemical nature of the thermoplastic blocks and elastomer blocks of which may vary.

1.1.1. Structure of the TPE

The number-average molecular weight (denoted Mn) of the TPE is preferably between 30 000 and 500 000 g/mol, more preferably between 40 000 and 400 000 g/mol. Below the minima indicated, there is a risk of the cohesion between the elastomer chains of the TPE being affected, in particular due to its possible dilution (in the presence of an extender oil); furthermore, there is a risk of an increase in the working temperature affecting the mechanical properties, in particular the properties at break, with the consequence of a reduced “hot” performance. Furthermore, an excessively high Mn weight can be detrimental to the processability. Thus, it has been found that a value within a range from 50 000 to 300 000 g/mol was particularly well suited.

The number-average molecular weight (Mn) of the TPE elastomer is determined, in a known way, by size exclusion chromatography (SEC). For example, in the case of thermoplastic styrene elastomers, the sample is dissolved beforehand in tetrahydrofuran at a concentration of approximately 1 g/l and then the solution is filtered through a filter with a porosity of 0.45 μm before injection. The apparatus used is a Waters Alliance chromatographic line. The elution solvent is tetrahydrofuran, the flow rate is 0.7 ml/min, the temperature of the system is 35° C. and the analytical time is 90 min. A set of four Waters columns in series, with the Styragel tradenames (HMW7, HMW6E and two HT6Es), is used. The injected volume of the solution of the polymer sample is 100 μl. The detector is a Waters 2410 differential refractometer and its associated software, for making use of the chromatographic data, is the Waters Millennium system. The calculated average molar masses are relative to a calibration curve produced with polystyrene standards. The conditions can be adjusted by those skilled in the art.

The value of the polydispersity index PDI (reminder: PDI=Mw/Mn, with Mw the weight-average molecular weight and Mn the number-average molecular weight) of the TPE is preferably less than 3, more preferably less than 2 and more preferably still less than 1.5.

In a known way, TPEs exhibit two glass transition temperature peaks (Tg, measured according to ASTM D3418), the lowest temperature being relative to the elastomer part of the TPE and the highest temperature being relative to the thermoplastic part of the TPE. Thus, the flexible blocks of the TPEs are defined by a Tg which is less than ambient temperature (25° C.), while the rigid blocks have a Tg which is greater than 80° C.

In order to be both elastomeric and thermoplastic in nature, the TPE has to be provided with blocks which are sufficiently incompatible (that is to say, different as a result of their respective weights, their respective polarities or their respective Tg values) to retain their own properties of elastomer block or thermoplastic block.

The TPEs can be copolymers with a small number of blocks (less than 5, typically 2 or 3), in which case these blocks preferably have high weights of greater than 15 000 g/mol.

These TPEs can, for example, be diblock copolymers, comprising a thermoplastic block and an elastomer block. These are often also triblock elastomers with two rigid segments connected by a flexible segment. The rigid and flexible segments can be positioned linearly, in a star or branched configuration. Typically, each of these segments or blocks often comprises a minimum of more than 5, generally of more than 10, base units (for example, styrene units and butadiene units for a styrene/butadiene/styrene block copolymer).

The TPEs can also comprise a large number of smaller blocks (more than 30, typically from 50 to 500), in which case these blocks preferably have low weights, for example from 500 to 5000 g/mol; these TPEs will subsequently be referred to as multiblock TPEs and are an elastomer block/thermoplastic block series.

According to a first alternative form, the TPE is provided in a linear form. For example, the TPE is a diblock copolymer: thermoplastic block/elastomer block. The TPE can also be a triblock copolymer: thermoplastic block/elastomer block/thermoplastic block, that is to say a central elastomer block and two terminal thermoplastic blocks at each of the two ends of the elastomer block. Equally, the multiblock TPE can be a linear series of elastomer blocks/thermoplastic blocks.

According to another alternative form of the invention, the TPE of use for the requirements of the invention is provided in a star-branched form comprising at least three branches. For example, the TPE can then be composed of a star-branched elastomer block comprising at least three branches and of a thermoplastic block located at the end of each of the branches of the elastomer block. The number of branches of the central elastomer can vary, for example, from 3 to 12 and preferably from 3 to 6.

According to another alternative form of the invention, the TPE is provided in a branched or dendrimer form. The TPE can then be composed of a branched or dendrimer elastomer block and of a thermoplastic block located at the end of the branches of the dendrimer elastomer block.

1.1.2. Nature of the Elastomer Blocks

The elastomer blocks of the TPE for the requirements of the invention can be any elastomer known to a person skilled in the art. They preferably have a Tg of less than 25° C., preferentially of less than 10° C., more preferentially of less than 0° C. and very preferentially of less than −10° C. Also preferentially, the elastomer block Tg of the TPE is greater than −100° C.

For the elastomer blocks comprising a carbon-based chain, if the elastomer part of the TPE does not comprise an ethylenic unsaturation, it will be referred to as a saturated elastomer block. If the elastomer block of the TPE comprises ethylenic unsaturations (that is to say, carbon-carbon double bonds), it will then be referred to as an unsaturated or diene elastomer block.

A saturated elastomer block is composed of a polymer sequence obtained by the polymerization of at least one (that is to say, one or more) ethylenic monomer, that is to say, a monomer comprising a carbon-carbon double bond. Mention may be made, among the blocks resulting from these ethylenic monomers, of polyalkylene blocks, such as ethylene/propylene or ethylene/butylene random copolymers. These saturated elastomer blocks can also be obtained by hydrogenation of unsaturated elastomer blocks. They can also be aliphatic blocks resulting from the family of the polyethers, polyesters or polycarbonates.

In the case of saturated elastomer blocks, this elastomer block of the TPE is preferably predominantly composed of ethylenic units. Predominantly is understood to mean the highest content by weight of ethylenic monomer, with respect to the total weight of the elastomer block, and preferably a content by weight of more than 50%, more preferably of more than 75% and more preferably still of more than 85%.

Conjugated C₄-C₁₄ dienes can be copolymerized with the ethylenic monomers. They are, in this case, random copolymers. Preferably, these conjugated dienes are chosen from isoprene, butadiene, 1-methylbutadiene, 2-methylbutadiene, 2,3-dimethyl-1,3-butadiene, 2,4-dimethyl-1,3-butadiene, 1,3-pentadiene, 2-methyl-1,3-pentadiene, 3-methyl-1,3-pentadiene, 4-methyl-1,3-pentadiene, 2,3-dimethyl-1,3-pentadiene, 1,3-hexadiene, 2-methyl-1,3-hexadiene, 3-methyl-1,3-hexadiene, 4-methyl-1,3-hexadiene, 5-methyl-1,3-hexadiene, 2,3-dimethyl-1,3-hexadiene, 2,4-dimethyl-1,3-hexadiene, 2,5-dimethyl-1,3-hexadiene, 2-neopentylbutadiene, 1,3-cyclopentadiene, 1,3-cyclohexadiene, 1-vinyl-1,3-cyclohexadiene or their mixture. More preferentially, the conjugated diene is isoprene or a mixture containing isoprene.

In the case of unsaturated elastomer blocks, this elastomer block of the TPE is preferably predominantly composed of a diene elastomer part. Predominantly is understood to mean the highest content by weight of diene monomer, with respect to the total weight of the elastomer block, and preferably a content by weight of more than 50%, more preferably of more than 75% and more preferably still of more than 85%. Alternatively, the unsaturation of the unsaturated elastomer block can originate from a monomer comprising a double bond and an unsaturation of cyclic type; this is the case, for example, in polynorbornene.

Preferably, conjugated C₄-C₁₄ dienes can be polymerized or copolymerized in order to form a diene elastomer block. Preferably, these conjugated dienes are chosen from isoprene, butadiene, piperylene, 1-methylbutadiene, 2-methylbutadiene, 2,3-dimethyl-1,3-butadiene, 2,4-dimethyl-1,3-butadiene, 1,3-pentadiene, 2-methyl-1,3-pentadiene, 3-methyl-1,3-pentadiene, 4-methyl-1,3-pentadiene, 2,3-dimethyl-1,3-pentadiene, 2,5-dimethyl-1,3-pentadiene, 2-methyl-1,4-pentadiene, 1,3-hexadiene, 2-methyl-1,3-hexadiene, 2-methyl-1,5-hexadiene, 3-methyl-1,3-hexadiene, 4-methyl-1,3-hexadiene, 5-methyl-1,3-hexadiene, 2,5-dimethyl-1,3-hexadiene, 2,5-dimethyl-2,4-hexadiene, 2-neopentyl-1,3-butadiene, 1,3-cyclopentadiene, methylcyclopentadiene, 2-methyl-1,6-heptadiene, 1,3-cyclohexadiene, 1-vinyl-1,3-cyclohexadiene or their mixture. More preferably, the conjugated diene is isoprene or butadiene or a mixture comprising isoprene and/or butadiene.

According to an alternative form, the monomers polymerized in order to form the elastomer part of the TPE can be randomly copolymerized with at least one other monomer, so as to form an elastomer block. According to this alternative form, the molar fraction of polymerized monomer, other than an ethylenic monomer, with respect to the total number of units of the elastomer block, has to be such that this block retains its elastomer properties. Advantageously, the molar fraction of this other comonomer can range from 0% to 50%, more preferably from 0% to 45% and more preferably still from 0% to 40%.

By way of illustration, this other monomer capable of copolymerizing with the first monomer may be selected from ethylenic monomers as defined above (for example ethylene), diene monomers, more particularly the conjugated diene monomers having from 4 to 14 carbon atoms as defined above (for example butadiene), monomers of vinylaromatic type having from 8 to 20 carbon atoms as defined below, or else it may be a monomer such as vinyl acetate.

When the comonomer is of vinylaromatic type, it advantageously represents a fraction of units, with regard to the total number of units of the thermoplastic block, from 0% to 50%, preferably ranging from 0% to 45% and more preferably still ranging from 0% to 40%. The styrene monomers mentioned above, namely methylstyrenes, para(tert-butyl)styrene, chlorostyrenes, bromostyrenes, fluorostyrenes or else para-hydroxystyrene, are suitable in particular as vinylaromatic compounds. Preferably, the comonomer of vinylaromatic type is styrene.

According to a preferred embodiment of the invention, the elastomer blocks of the TPE exhibit, in total, a number-average molecular weight (“Mn”) ranging from 25 000 g/mol to 350 000 g/mol, preferably from 35 000 g/mol to 250 000 g/mol, so as to confer, on the TPE, good elastomeric properties.

The elastomer block can also be a block comprising several types of ethylene, diene or styrene monomers as defined above.

The elastomer block can also consist of several elastomer blocks as defined above.

1.1.3. Nature of the Thermoplastic Blocks

Use will be made, for the definition of the thermoplastic blocks, of the characteristic of glass transition temperature (Tg) of the rigid thermoplastic block. This characteristic is well known to a person skilled in the art. It makes it possible in particular to choose the industrial processing (transformation) temperature. In the case of an amorphous polymer (or polymer block), the processing temperature is chosen to be substantially greater than the Tg. In the specific case of a semicrystalline polymer (or polymer block), a melting point may be observed which is then greater than the glass transition temperature. In this case, it is instead the melting point (Tm) which makes it possible to choose the processing temperature for the polymer (or polymer block) under consideration. Thus, subsequently, when reference is made to “Tg (or Tm, if appropriate)”, it will be necessary to consider that this is the temperature used to choose the processing temperature.

For the requirements of the invention, the TPE elastomers comprise one or more thermoplastic block(s) preferably having a Tg (or Tm, if appropriate) of greater than or equal to 80° C. and formed from polymerized monomers. Preferably, this thermoplastic block has a Tg (or Tm, if appropriate) within a range varying from 80° C. to 250° C. Preferably, the Tg (or Tm, if appropriate) of this thermoplastic block is preferably from 80° C. to 200° C., more preferably from 80° C. to 180° C.

The proportion of the thermoplastic blocks, with respect to the TPE as defined for the implementation of the invention, is determined, on the one hand, by the thermoplasticity properties which said copolymer has to exhibit. The thermoplastic blocks having a Tg (or Tm, if appropriate) of greater than or equal to 80° C. are preferentially present in proportions sufficient to retain the thermoplastic nature of the elastomer according to the invention. The minimum content of thermoplastic blocks having a Tg (or Tm, if appropriate) of greater than or equal to 80° C. in the TPE can vary as a function of the conditions of use of the copolymer. On the other hand, the ability of the TPE to deform during the preparation of the tyre can also contribute to determining the proportion of the thermoplastic blocks having a Tg (or Tm, if appropriate) of greater than or equal to 80° C.

The thermoplastic blocks having a Tg (or Tm, if appropriate) of greater than or equal to 80° C. can be formed from polymerized monomers of various natures; in particular, they can constitute the following blocks or the mixtures thereof:

polyolefins (polyethylene, polypropylene);

polyurethanes;

polyamides;

polyesters;

polyacetals;

polyethers (polyethylene oxide, polyphenylene ether);

polyphenylene sulfides;

polyfluorinated compounds (FEP, PFA, ETFE);

polystyrenes (described in detail below);

polycarbonates;

polysulfones;

polymethyl methacrylate;

polyetherimide;

thermoplastic copolymers, such as the acrylonitrile/butadiene/styrene (ABS) copolymer.

The thermoplastic blocks having a Tg (or Tm, if appropriate) of greater than or equal to 80° C. can also be obtained from monomers chosen from the following compounds and the mixtures thereof:

acenaphthylene: those skilled in the art may refer, for example, to the paper by Z. Fodor and J. P. Kennedy, Polymer Bulletin, 1992, 29(6), 697-705;

indene and its derivatives, such as, for example, 2-methylindene, 3-methylindene, 4-methylindene, dimethylindenes, 2-phenylindene, 3-phenylindene and 4-phenylindene; those skilled in the art may, for example, refer to the patent document U.S. Pat. No. 4,946,899, by, the inventors Kennedy, Puskas, Kaszas and Hager, and to the documents J. E. Puskas, G. Kaszas, J. P. Kennedy and W. G. Hager, Journal of Polymer Science, Part A: Polymer Chemistry (1992), 30, 41, and J. P. Kennedy, N. Meguriya and B. Keszler, Macromolecules (1991), 24(25), 6572-6577;

isoprene, then resulting in the formation of a certain number of trans-1,4-polyisoprene units and of units cyclized according to an intramolecular process; those skilled in the art may, for example, refer to the documents G. Kaszas, J. E. Puskas and J. P. Kennedy, Applied Polymer Science (1990), 39(1), 119-144, and J. E. Puskas, G. Kaszas and J. P. Kennedy, Macromolecular Science, Chemistry A28 (1991), 65-80.

The polystyrenes are obtained from styrene monomers. Styrene monomer should be understood as meaning, in the present description, any monomer comprising styrene, unsubstituted or substituted; mention may be made, among substituted styrenes, for example, of methylstyrenes (for example, o-methylstyrene, m-methylstyrene or p-methylstyrene, α-methylstyrene, α,2-dimethylstyrene, α,4-dimethylstyrene or diphenylethylene), para-(tert-butyl)styrene, chlorostyrenes (for example, o-chlorostyrene, m-chlorostyrene, p-chlorostyrene, 2,4-dichlorostyrene, 2,6-dichlorostyrene or 2,4,6-trichlorostyrene), bromostyrenes (for example, o-bromostyrene, m-bromostyrene, p-bromostyrene, 2,4-dibromostyrene, 2,6-dibromostyrene or 2,4,6-tribromostyrenes), fluorostyrenes (for example, o-fluorostyrene, m-fluorostyrene, p-fluorostyrene, 2,4-difluorostyrene, 2,6-difluorostyrene or 2,4,6-trifluorostyrenes) or else para-hydroxystyrene.

According to a preferential embodiment of the invention, the content by weight of styrene in the TPE elastomer is between 5% and 50%. Below the minimum indicated, there is a risk of the thermoplastic nature of the elastomer being substantially reduced while, above the recommended maximum, the elasticity can be affected. For these reasons, the styrene content is more preferentially between 10% and 40%.

According to an alternative form of the invention, the polymerized monomer as defined above can be copolymerized with at least one other monomer, so as to form a thermoplastic block having a Tg (or Tm, if appropriate) as defined above.

By way of illustration, this other monomer capable of copolymerizing with the polymerized monomer can be chosen from diene monomers, more particularly conjugated diene monomers having from 4 to 14 carbon atoms, and monomers of vinylaromatic type having from 8 to 20 carbon atoms, such as defined in the part relating to the elastomer block.

According to the invention, the thermoplastic blocks of the TPE exhibit, in total, a number-average molecular weight (“Mn”) ranging from 5000 g/mol to 150 000 g/mol, so as to confer, on the TPE, good elastomeric properties and a mechanical strength which is sufficient and compatible with tyre use.

The thermoplastic block can also consist of several thermoplastic blocks as defined above.

1.1.4. TPE Examples

For example, the TPE is a copolymer, the elastomer part of which is saturated and which comprises styrene blocks and alkylene blocks. The alkylene blocks are preferably of ethylene, propylene or butylene. More preferably, this TPE elastomer is selected from the following group consisting of diblock or triblock copolymers which are linear or star-branched: styrene/ethylene/butylene (SEB), styrene/ethylene/propylene (SEP), styrene/ethylene/ethylene/propylene (SEEP), styrene/ethylene/butylene/styrene (SEBS), styrene/ethylene/propylene/styrene (SEPS), styrene/ethylene/ethylene/propylene/styrene (SEEPS), styrene/isobutylene (SIB), styrene/isobutylene/styrene (SIBS) and the mixtures of these copolymers.

According to another example, the TPE is a copolymer, the elastomer part of which is unsaturated and which comprises styrene blocks and diene blocks, these diene blocks being in particular isoprene or butadiene blocks. More preferably, this TPE elastomer is selected from the following group consisting of diblock or triblock copolymers which are linear or star-branched: styrene/butadiene (SB), styrene/isoprene (SI), styrene/butadiene/isoprene (SBI), styrene/butadiene/styrene (SBS), styrene/isoprene/styrene (SIS), styrene/butadiene/isoprene/styrene (SBIS) and the mixtures of these copolymers.

For example again, the TPE is a linear or star-branched copolymer, the elastomer part of which comprises a saturated part and an unsaturated part, such as, for example, styrene/butadiene/butylene (SBB), styrene/butadiene/butylene/styrene (SBBS) or a mixture of these copolymers.

Mention may be made, among multiblock TPEs, of the copolymers comprising random copolymer blocks of ethylene and propylene/polypropylene, polybutadiene/polyurethane (TPU), polyether/polyester (COPE) or polyether/polyamide (PEBA).

It is also possible for the TPEs given as example above to be mixed with one another within the TPE matrix according to the invention.

Mention may be made, as examples of commercially available TPE elastomers, of the elastomers of SEPS, SEEPS or SEBS type sold by Kraton under the Kraton G name (e.g., G1650, G1651, G1654 and G1730 products) or Kuraray under the Septon name (e.g., Septon 2007, Septon 4033 or Septon 8004), or the elastomers of SIS type sold by Kuraray under the name Hybrar 5125 or sold by Kraton under the name D1161, or else the elastomers of linear SBS type sold by Polimeri Europa under the name Europrene SOL T 166 or of star-branched SBS type sold by Kraton under the name D1184. Mention may also be made of the elastomers sold by Dexco Polymers under the name Vector (e.g. Vector 4114 or Vector 8508). Mention may be made, among multiblock TPEs, of the Vistamaxx TPE sold by Exxon; the COPE TPE sold by DSM under the Arnitel name or by DuPont under the Hytrel name or by Ticona under the Riteflex name; the PEBA TPE sold by Arkema under the PEBAX name; or the TPU TPE sold by Sartomer under the name

TPU 7840 or by BASF under the Elastogran name.

1.1.5. Amount of TPE in the Polymeric Matrix

If optional other (non-thermoplastic) elastomers are used in the polymeric matrix, the TPE elastomer or elastomers constitute the predominant fraction by weight; they then represent at least 50% by weight, more preferably at least 75% by weight relative to the total weight of the polymeric matrix. Preferably again, the TPE elastomer or elastomers represent at least 90%, or even 95% (in particular 100%) by weight relative to the total weight of the polymeric matrix.

Thus, the amount of TPE elastomer is within a range which varies from 50 to 100 phr, from 75 to 100 phr, from 90 to 100 phr, from 95 to 100 phr.

1.2. Non-Thermoplastic Elastomer

The polymeric matrix according to the invention may comprise at least one (that is to say, one or more) diene rubber as non-thermoplastic elastomer, it being possible for this diene rubber to be used alone or as a blend with at least one (that is to say, one or more) other non-thermoplastic rubber or elastomer.

The total content of optional non-thermoplastic elastomer is within a range varying from 0 to 50 phr, preferably from 0 to 25 phr, more preferably from 0 to 10 phr, or even from 0 to 5 phr. Also very preferentially, the polymeric matrix according to the invention does not contain a non-thermoplastic elastomer.

Diene elastomer should be understood, according to the invention, as meaning any polymer resulting, at least in part (i.e., a homopolymer or a copolymer), from diene monomers (monomers bearing two conjugated or non-conjugated carbon-carbon double bonds). Diene elastomer capable of being used in the invention is understood more particularly to mean a diene elastomer corresponding to one of the following categories:

(a) any homopolymer obtained by polymerization of a conjugated diene monomer having from 4 to 12 carbon atoms;

(b) any copolymer obtained by copolymerization of one or more of the conjugated dienes mentioned below with one another or with one or more ethylenically unsaturated monomers;

(c) any homopolymer obtained by polymerization of a non-conjugated diene monomer having from 5 to 12 carbon atoms;

(d) any copolymer obtained by copolymerization of one or more of the non-conjugated dienes mentioned below with one another or with one or more ethylenically unsaturated monomers;

(e) natural rubber;

(f) a mixture of several of the elastomers defined in (a) to (f) with one another.

Mention may be made, as conjugated diene monomer appropriate for the synthesis of the elastomers, of 1,3-butadiene (hereinafter denoted butadiene), 2-methyl-1,3-butadiene, 2,3-di(C₁-C₅ alkyl)-1,3-butadienes, such as, for example, 2,3-dimethyl-1,3-butadiene, 2,3-diethyl-1,3-butadiene, 2-methyl-3-ethyl-1,3-butadiene or 2-methyl-3-isopropyl-1,3-butadiene, an aryl-1,3-butadiene, 1,3-pentadiene or 2,4-hexadiene.

Mention may be made, as non-conjugated diene monomer appropriate for the synthesis of the elastomers, of 1,4-pentadiene, 1,4-hexadiene, ethylidenenorbornene or dicyclopentadiene.

Mention may be made, as ethylenically unsaturated monomers capable of playing a part in the copolymerization with one or more conjugated or non-conjugated diene monomers, in order to synthesize the elastomers, of:

vinylaromatic compounds having from 8 to 20 carbon atoms, such as, for example, styrene, ortho-, meta- or para-methylstyrene, the vinylmesitylene commercial mixture, divinylbenzene or vinylnaphthalene;

(non-aromatic) monoolefins, such as, for example, ethylene and a-olefins, in particular propylene or isobutene;

(meth)acrylonitrile or (meth)acrylic esters.

Among these, the diene polymer or polymers used in the invention are very particularly selected from the group of the diene polymers consisting of polybutadienes (abbreviated to “BRs”), synthetic polyisoprenes (IRs), natural rubber (NR), butadiene copolymers, isoprene copolymers, copolymers of ethylene and of diene, and the mixtures of these polymers. Such copolymers are more preferably selected from the group consisting of butadiene/styrene copolymers (SBRs), isoprene/butadiene copolymers (BIRs), isoprene/styrene copolymers (SIRs), isoprene/butadiene/styrene copolymers (SBIRs), halogenated or non-halogenated butyl rubbers, and copolymers of ethylene and of butadiene (EBRs).

1.3 Non-Elastomeric Thermoplastic

The polymeric matrix according to the invention may comprise at least one non-elastomeric thermoplastic.

The total content of optional non-elastomeric thermoplastic is within a range varying from 0 to 50% by weight, preferably between 0 and 25% by weight, more preferably between 0 and 10% by weight, or even 0 and 5% by weight, relative to the total weight of the polymeric matrix. Very preferentially, the polymeric matrix according to the invention does not contain a non-elastomeric thermoplastic.

Among the non-elastomeric thermoplastics, mention may be made of low-density polyethylene (LDPE), polypropylene (PP), polystyrene (PS), polymethyl methacrylate (PMMA), aliphatic polyamides and polyesters. Among the aliphatic polyamides, mention may in particular be made of the polyam ides 4-6, 6, 6-6, 11 or 12. Mention may be made, among the polyesters, for example, of PET (polyethylene terephthalate), PEN (polyethylene naphthalate), PBT (polybutylene terephthalate), PBN (polybutylene naphthalate), PPT (polypropylene terephthalate) and PPN (polypropylene naphthalate).

1.4 Piezoelectric Inorganic Fillers

The piezoelectric inorganic fillers comprise inorganic piezoelectric compounds. These may be piezoelectric single crystals or piezoelectric ceramics.

The piezoelectric single crystals are in particular natural piezoelectric materials such as quartz or tourmaline. Ferroelectric crystals may have a domain structure. Monodomain and polydomain single crystals can be distinguished according to whether one or more polarization directions coexist in the crystal.

Ceramics are piezoelectric materials with strong electromechanical coupling and high density. Ceramics derive their piezoelectric property from their crystalline structure, through the lack of symmetry of the crystal lattice which dissociates the centres of gravity of the positive and negative charges, each lattice then constituting an electric dipole. The crystal lattice thus has a permanent dipole which gives these materials high dielectric permittivity values. Synthetic ceramics are in particular composed of ferroelectric oxides, which have the property of possessing an electric polarization in the spontaneous state, which can furthermore be reversed by the application of a sufficiently intense external electric field.

Advantageously, the piezoelectric inorganic fillers are piezoelectric ceramics.

Advantageously, the piezoelectric inorganic fillers are ferroelectric oxides.

The ferroelectric oxides may in have particular a perovskite structure. They correspond advantageously to a general formula ABO₃ such as barium titanate (BaTiO₃), lead titanate (PbTiO₃), potassium niobate (KNbO₃), lead niobate (PbNbO₃) or bismuth ferrite (BiFeO₃). In this family of piezoelectric materials, mention may also be made of lead zirconate titanate (PZT) with a Pb(ZrₓTi₁₋ₓ)O₃ structure in which x is between 0 and 1. It may be in pure form or in the form of semiconductor doped with either acceptor dopants (to give a so-called hard PZT), such as Fe, Co, Mn, Mg, Al, In, Cr, Sc, Na or K, or with donor dopants (to give a so-called soft PZT), such as La, Nd, Sb, Ta, Nb or W.

As nonlimiting examples, the piezoelectric inorganic fillers may be selected from the group comprising barium titanate, lead titanate, lead zirconate titanate (PZT), lead niobate, lithium niobate and potassium niobate, advantageously the piezoelectric inorganic fillers are barium titanate fillers.

Both barium titanate and potassium niobate are lead-free piezoelectric materials. They have the advantage of being less toxic.

The most well-known piezoelectric ceramics are barium titanate (BaTiO₃) and lead zirconate titanate (PZT), which have a very good electromechanical coefficient and offer a variety of manufacturing processes. The latter (sol-gel process, hydrothermal synthesis, calcination, etc.) make it possible to modify the dielectric, mechanical and piezoelectric properties depending on the intended application.

In particular, the fillers have particle sizes of between 50 nm and 500 μm. The size of the particles corresponds to the average diameter of the particles. The measurement of the average diameter is performed by scanning electron microscopy (SEM) analysis. Photographs are taken on powder samples. Image analysis is carried out using software and makes it possible to attain the average diameter of the particles present.

The Curie temperature, Tc, of a piezoelectric material corresponds to the temperature at which the material becomes paraelectric. Thus, the characteristic hysteresis cycle of the piezoelectric material, which is obtained by plotting the polarization as a function of the electric field applied to the material, disappears when the Curie temperature is reached. The Curie temperature is characteristic of the piezoelectric material.

The Curie temperature, Tc, of the inorganic fillers included in a piezoelectric composite according to the invention is greater than the glass transition temperature, Tg, of each thermoplastic block of the thermoplastic elastomer TPE and also the melting temperature, Tm, of said thermoplastic blocks when it exists.

1.5 Piezoelectric Composite

One subject of the present invention is a piezoelectric composite comprising piezoelectric inorganic fillers dispersed in the form of individual particles in a polymeric matrix, characterized in that the polymeric matrix comprises a thermoplastic elastomer (TPE), in that the glass transition temperature, Tg, of each thermoplastic block of the thermoplastic elastomer (TPE) is lower than the lowest Curie temperature, Tc, of the piezoelectric inorganic fillers, moreover when the thermoplastic blocks have a melting point, Tm, said melting point of each thermoplastic block is also lower than the lowest Curie temperature of the piezoelectric inorganic fillers, and in that the filler content of the piezoelectric inorganic fillers is at least 5% by volume relative to the total volume of polymeric matrix.

In particular, the content of piezoelectric inorganic fillers varies from 5% to 80% by volume relative to the total volume of polymeric matrix, advantageously from 5% to 60%, more advantageously still from 5% to 30%. The content of piezoelectric inorganic fillers is at least 5% by volume, in particular at least 6% by volume, or even 7% by volume relative to the total volume of polymeric matrix.

Advantageously, the piezoelectric composite is of 0-3 connectivity, comprising particles of piezoelectric fillers dispersed in the polymeric matrix. The connectivity depends on the spatial organization of each constituent phase of the composite material. A change in connectivity results in major changes in the physical properties of the composites. In the case of two-phase systems, the nature of the connectivity is represented by two numbers (the first for the ceramic, the second for the matrix). They indicate the number of directions connected by the phase considered. Thus, a 0-3 connectivity composite corresponds to a composite consisting of piezoelectric powder grains dispersed in the polymeric matrix. The main advantage of this type of composite is the ease of implementation of the process, or else the ease of producing complex shapes, such as curved surfaces.

1.6 Polarization of the Piezoelectric Composite

The step of polarizing the piezoelectric composite corresponds to the application of an electric field to the terminals of the electroactive composite in order to orient the dipoles of the piezoelectric fillers in the same direction in order to obtain a macroscopic polarization of the composite.

The polarization depends on the polarization temperature, the applied electric field and the polarization time.

Advantageously, the polarization temperature is greater than the glass transition temperature, Tg, of each thermoplastic block of the thermoplastic elastomer TPE. In fact, above the glass transition temperature of each thermoplastic block of the thermoplastic elastomer TPE, the dielectric permittivity of the polymer increases, favouring the adjustment of permittivity between polymer and ceramic particles.

Advantageously, the polarization temperature is at least 5° C. lower than the lowest Curie temperature, Tc, of the piezoelectric inorganic fillers. Indeed, close to the Curie temperature of the piezoelectric inorganic fillers, the agitation of the dipoles makes it more difficult to align them under an electric field.

Advantageously, the polarization temperature is between the glass transition temperature, Tg, of each thermoplastic block of the thermoplastic elastomer TPE and 5° C. lower than the lowest Curie temperature, Tc, of the piezoelectric inorganic fillers.

Advantageously, the polarization temperature is between the glass transition temperature, Tg, of each thermoplastic block of the thermoplastic elastomer TPE and at least 7° C. lower, more advantageously still at least 10° C. lower than the lowest Curie temperature, Tc, of the piezoelectric inorganic fillers.

In particular, the electric field applied during the polarization step is between 0.5 and 8 kV/mm, advantageously between 0.75 and 4 kV/mm.

In particular, the applied electric field depends on the nature of the piezoelectric filler and the polarization time of the piezoelectric composite. A person skilled in the art knows how to adapt the electric field to the piezoelectric filler and to the polarization time.

In particular, the polarization time is between 1 minute and 10 hours, preferably between 5 minutes and 2 hours.

1.7 Process

The piezoelectric composite according to the invention is produced from a polymeric matrix and piezoelectric inorganic fillers.

It may be obtained by bulk mixing means such as extrusion or another batch process.

By way of example, the thermoplastic elastomer TPE is dissolved in a solvent to obtain a TPE solution. The piezoelectric material is introduced into the TPE solution to give a suspension which is then stirred. The suspension is sonified, then the solvent is evaporated to obtain the piezoelectric composite according to the invention.

The piezoelectric composite may also be produced by extrusion or in an internal mixer.

1.8 Use

One subject of the invention is in particular a device comprising the piezoelectric composite according to the invention and electrodes.

The electrodes are known to those skilled in the art. They are preferentially flexible, such as a TPE or diene mixture that is rendered conductive or a conductive ink or lacquer. They may also be in the form of a thin deposit of metals, such as a fine deposit of gold or silver.

The electrodes are deposited on the faces of the piezoelectric composite according to the invention in order to collect the charges emitted by said composite.

The device is advantageously connected to an electronic member in order to capture the emitted electrical pulses and to use this information.

Another subject of the invention is the use of the device as mentioned above in combination with a sensor.

Another subject of the invention is a tyre comprising the device mentioned above comprising the piezoelectric composite according to the invention and electrodes. In particular, said device is fastened to the inner airtight layer of said tyre. The fastening may be achieved by conventional means known to those skilled in the art such as the scraping of the wash, the use of cold vulcanization or the melting of TPE. The fastening may be carried out by adhesive bonding.

### EXAMPLES

Composite:
Thermoplastic elastomer matrix: SIS poly(styrene-isoprene-styrene) copolymer-D1163 from Kraton (density=0.94)
Piezoelectric inorganic fillers: BaTiO₃: average diameter 500 nm or 700 nm, density 5.85 g/cm³—Inframat Advanced Materials

Formulation:
Filler content: variable from 0 to 26% by volume relative to the total volume of polymeric matrix

Preparation Process:
Liquid mixing in solvent
Shape of test specimens: parallelepiped of Length×Width×Thickness: 3×1.5×1 (mm)
Surface area of the electrodes on the test specimens: Length×Width: 2.5×1 (mm)

Polarization Conditions:
Time: 1 h
Temperature: 100° C.
Electric field: 4.5 kV/mm

Measurement of the Amount of Electric Charge Emitted:
Metravib DMA with specific tension jaws for capturing the charges collected on the electrodes of the composites>Charge amplifier>Oscilloscope
Stress mode: variable extension from 0.01% to 2% depending on the matrix

### Example 1

### Effect of the Filler Content

500 nm particles—Dynamic stress: 2% deformation at 1 Hz

TABLE 1

| | 1 | 2 | 3 | 4 |
|---|---|---|---|---|
| SIS D1163 (phr) | 100 | 100 | 100 | 100 |
| BaTiO₃ (phr) | 0 | 32.8 | 69.1 | 155.6 |
| Vol. fraction BaTiO₃ (% vol) | 0 | 5.6 | 11.6 | 26.0 |
| Q (pC) | 2 | 32 | 69 | 138 |
| d31 (pC/N) | 0.2 | 2.4 | 4.3 | 5.9 |

700 nm particles—Dynamic stress: 2% deformation at 1 Hz

TABLE 2

| | 1 | 2 | 3 | 4 |
|---|---|---|---|---|
| SIS D1163 (phr) | 100 | 100 | 100 | 100 |
| BaTiO₃ (phr) | 0 | 32.8 | 69.1 | 155.6 |
| Vol. fraction BaTiO₃ (% vol) | 0 | 5.6 | 11.6 | 26 |
| Q (pC) | 2 | 24 | 32 | 72 |
| d31 (pC/N) | 0.2 | 1.7 | 1.9 | 3.0 |

Conclusion: The content of ferroelectric ceramic particles has a direct impact on the amount of electric charge restored for one and the same deformation. The piezoelectric behaviour of the composite is observed from 5% by volume of piezoelectric charges. The various particle diameters make it possible to obtain composites having a piezoelectric activity.

### Example 2

### Effect of the Degree of Deformation—Comparison of Matrices

(1) Thermoplastic elastomer (TPE) matrix: SIS poly(styrene-isoprene-styrene) copolymer—D1163 from Kraton (density=0.94)
(2) Thermoplastic (TP) matrix: polypropylene homopolymer—100GA12 from INEOS (density=0.92)
(3) Thermosetting (TD) matrix: epoxy resin with amine hardener—SR1660 and SD2630 from SICOMIN (density=1.15 and 1)

1 (TPE): example according to the invention.

2 (TP) and 3 (TD): comparative examples.

700 nm particles—filler content: 11% by volume relative to the total volume of polymeric matrix

TABLE 3

| | 1 (TPE) | 2 (TP) | 3 (TD) |
|---|---|---|---|
| SIS D1163 (phr) | 100 | | |
| PP 100GA12 (phr) | | 100 | |
| Resin SR1660 (phr) | | | 77 |
| Hardener SR2630 (phr) | | | 23 |
| BaTiO₃ (phr) | 69.2 | 70.7 | 65.0 |

d31 (pC/N) according to the deformation

| | | | |
|---|---|---|---|
| 0.01% deformation | — | — | 0.03 |
| 0.05% deformation | — | — | 0.02 |
| 0.1% deformation | 2.0 | 0.0 | 0.02 |
| 0.5% deformation | 1.6 | 0.01 | Break |
| 1% deformation | 1.5 | 0.01 | — |
| 2% deformation | 1.8 | Plastic deformation | — |

Conclusion: At the same level of mechanical deformation the amount of electric charge emitted is greater in the case of the composite comprising a TPE thermoplastic elastomer matrix. Furthermore, the deformation usage range of the composite comprising a TPE thermoplastic elastomer matrix is greater. Specifically, with a thermosetting matrix, the composite is damaged after 0.1% deformation; with a thermoplastic matrix, a plastic deformation that is not reversible without energy input is observed after 1% deformation. On the contrary, with a TPE matrix, the composite is usable above 2% deformation, the limit in this example being related to the operating limit of the electrode which is weaker than the TPE-based composite.

### Example 3

### Effect of the Polarization Temperature

700 nm particles—filler content: 26% by volume relative to the total volume of polymeric matrix

TABLE 4

| | 1 | | | | |
|---|---|---|---|---|---|
| SIS D1163 (phr) | 100 | | | | |
| BaTiO₃ (phr) | 155.6 | | | | |
| Polarization temperature (° C.) | 30 | 55 | 80 | 100 | 120 |
| d31 (pC/N) | 0.1 | 0.1 | 1.8 | 3.0 | 0.7 |

Conclusion: The polarization temperature has an impact on the amount of charge emitted by the piezoelectric composite. Having a matrix in which the thermoplastic blocks have a glass transition temperature, Tg, lower than the Curie temperature, Tc, of the ferroelectric ceramic makes it possible to polarize at a temperature that will make the phenomenon more effective. In this example, the Tc of the BaTiO₃ piezoelectric charges is of the order of 130° C.

1.-16. (canceled)

17. A piezoelectric composite comprising:
a polymeric matrix; and
piezoelectric inorganic fillers in the form of particles which are not bound to the polymeric matrix but are dispersed in the polymeric matrix,
wherein the polymeric matrix comprises a thermoplastic elastomer,
wherein a glass transition temperature Tg of each thermoplastic block of the thermoplastic elastomer is lower than a lowest Curie temperature Tc of the piezoelectric inorganic fillers, and, when a thermoplastic block has a melting point Tm, the melting point of the thermoplastic block is lower than the lowest Curie temperature of the piezoelectric inorganic fillers, and
wherein a content of the piezoelectric inorganic fillers is at least 5% by volume relative to a total volume of the polymeric matrix.

18. The piezoelectric composite according to claim 17, wherein the glass transition temperature and, when applicable, the melting point of each thermoplastic block of the thermoplastic elastomer is greater than or equal to 80° C.

19. The piezoelectric composite according to claim 17, wherein the glass transition temperature of the elastomer blocks of the thermoplastic elastomer is less than 25° C.

20. The piezoelectric composite according to claim 17, wherein the thermoplastic elastomer is a copolymer selected from the group consisting of styrene/butadiene (SB), styrene/isoprene (SI), styrene/butadiene/isoprene (SBI), styrene/butadiene/styrene (SBS), styrene/isoprene/styrene (SIS), and styrene/butadiene/isoprene/styrene (SBIS) copolymers and mixtures thereof.

21. The piezoelectric composite according to claim 17, wherein the content of piezoelectric inorganic fillers varies from 5% to 80% by volume relative to the total volume of the polymeric matrix.

22. The piezoelectric composite according to claim 17, wherein a size of the piezoelectric inorganic fillers varies from 50 nm to 500 μm.

23. The piezoelectric composite according to claim 17, wherein the piezoelectric inorganic fillers are piezoelectric ceramics.

24. The piezoelectric composite according to claim 17, wherein the piezoelectric inorganic fillers are selected from the group comprising barium titanate, lead titanate, lead zirconate titanate (PZT), lead niobate, lithium niobate and potassium niobate fillers.

25. The piezoelectric composite according to claim 17, wherein the thermoplastic elastomer represents at least 90% by weight relative to the total weight of the polymeric matrix.

26. A process for preparing a piezoelectric composite according to claim 17 comprising a step of:
polarizing the piezoelectric composite.

27. The process according to claim 26, wherein the polarization temperature is between the glass transition temperature Tg of each thermoplastic block and at least 5° C. lower than the lowest Curie temperature Tc of the piezoelectric inorganic fillers.

28. The process according to claim 26, wherein the polarization temperature is between the glass transition temperature Tg of each thermoplastic block and at least 7° C. lower than the lowest Curie temperature Tc of the piezoelectric inorganic fillers.

29. A device comprising:
the piezoelectric composite according to claim 17; and
electrodes.

30. A tire comprising the device according to claim 29.

31. The tire according to claim 30 in which the device is fastened to an inner airtight layer of the tire.
